(19) United States
(12) Patent Application Publication
(10) Pub. No.: US 2023/0006421 A1
(43) Pub. Date: Jan. 5, 2023

(54) VERTICAL CAVITY SURFACE EMITTING LASER ELEMENT, VERTICAL CAVITY SURFACE EMITTING LASER ELEMENT ARRAY, VERTICAL CAVITY SURFACE EMITTING LASER MODULE, AND METHOD OF PRODUCING VERTICAL CAVITY SURFACE EMITTING LASER ELEMENT

(71) Applicant: SONY GROUP CORPORATION, TOKYO (JP)

(72) Inventors: TOMOMASA WATANABE, TOKYO (JP); RINTARO KODA, KANAGAWA (JP)

(21) Appl. No.: 17/757,237

(22) PCT Filed: Dec. 8, 2020
(86) PCT No.: PCT/JP2020/045570

§ 371 Date: Jun. 13, 2022

(30) Foreign Application Priority Data
Dec. 20, 2019 (JP) 2019-230751

(51) Int. Cl. H01S 5/183; H01S 5/343; H01S 5/42

(52) U.S. Cl. CPC H01S 5/18308; H01S 5/34313; H01S 5/34353; H01S 5/3438; H01S 5/423

(57) ABSTRACT

[Object] To provide a vertical cavity surface emitting laser element having a structure whose pitch can be narrowed, a vertical cavity surface emitting laser element array, a vertical cavity surface emitting laser module, and a method of producing a vertical cavity surface emitting laser element.

[Solving Means] A vertical cavity surface emitting laser element according to the present technology includes: a first substrate; and a second substrate. The first substrate is provided with a semiconductor layer including an active layer and a first distributed Bragg reflector (DBR) layer. The second substrate is provided with a constriction layer and a second DBR layer, the constriction layer having a constriction region and an injection region having conductivity higher than that of the constriction region, the second substrate being bonded to the first substrate such that the constriction layer is adjacent to the semiconductor layer.

### TECHNICAL FIELD

The present technology relates to a vertical cavity surface emitting laser element having a current constriction structure, a vertical cavity surface emitting laser element array, a vertical cavity surface emitting laser module, and a method of a producing vertical cavity surface emitting laser element.

### BACKGROUND ART

A vertical cavity surface emitting laser (VCSEL) element has a structure in which an active layer in which light emission is generated is sandwiched between a pair of distributed Bragg reflectors (DBRs). In the VCSEL element, a constriction structure is provided to collect a current flowing through the active layer and light generated in the active layer on a predetermined region.

For example, the constriction structure of a GaAs VCSEL element is generally an oxidized constriction structure obtained by oxidizing part of an AlAs layer close to the active layer to AlO with water vapor. This oxidized constriction structure is a structure having a small diffraction loss and excellent productivity, but it is difficult to control the oxidization depending on the process quality level at the time of forming a mesa (plateau-like structure). When the oxidization rate locally fluctuates, the optical aperture (OA) diameter varies and the beam properties are affected. Specifically, the pitch of the VCSEL element in a realistic device design was up to 14 μm, and there was a limit to narrow the pitch to 10 μm or less.

Further, in an InP VCSEL element, since there is no material that can be constricted by oxidization, a structure an oxidized constriction structure is formed on a GaAs substrate and wafer bonding is performed has been developed. Since also this structure has undergone an oxidization constriction process, it is necessary to form a mesa similarly to the existing structure and it is difficult to narrow the pitch.

Meanwhile, also a structure in which a constriction structure is formed in the vicinity of an active layer by wafer bonding has been reported. In accordance with Patent Literature 1, a transparent substrate is used, thermal performance is favorable because an active layer is close to a heat sink, and performance such as a threshold current, a threshold voltage, single mode stability, efficiency, and output power improved as compared with those of the existing VCSEL element is shown.

### CITATION LIST

### Patent Literature

Patent Literature 1: Japanese Patent Application Laid-open No. 1997-172229

### DISCLOSURE OF INVENTION

### Technical Problem

However, in the configuration of Patent Literature 1, since a substrate on which a constriction structure has been formed is attached to a substrate on which an active layer has been provided but a DBR layer is provided also between the constriction structure and the active layer, the current confinement in the layer surface direction and the light confinement in the lamination direction are not sufficient, and there is a limit to narrow the pitch.

In view of the circumstances as described above, it is an object of the present technology to provide a vertical cavity surface emitting laser element having a structure whose pitch can be narrowed, a vertical cavity surface emitting laser element array, a vertical cavity surface emitting laser module, and a method of producing a vertical cavity surface emitting laser element.

### Solution to Problem

In order to achieve the above-mentioned object, a vertical cavity surface emitting laser element according to an embodiment of the present technology includes: a first substrate; and a second substrate.

The first substrate is provided with a semiconductor layer including an active layer and a first distributed Bragg reflector (DBR) layer.

The second substrate is provided with a constriction layer and a second DBR layer, the constriction layer having a constriction region and an injection region having conductivity higher than that of the constriction region, the second substrate being bonded to the first substrate such that the constriction layer is adjacent to the semiconductor layer.

With this configuration, in the vertical cavity surface emitting laser element, the first substrate and the second substrate are bonded to each other. For this reason, a second substrate can be bonded to a first substrate after forming a constriction region and an injection region on the second substrate, and the pitch of a vertical cavity surface emitting laser element can be narrowed by forming the constriction region and the injection region by a method capable of narrowing the pitch.

The constriction region and the injection region may have a refractive index difference.

The constriction region may be formed in a ring shape surrounding the injection region.

The constriction region may be a gap provided in the constriction layer.

The injection region may be formed of a conductive material, and

the constriction region may be formed of a material obtained by applying non-conductive treatment to the conductive material.

The injection region may be formed of GaAs, and

the constriction region may be formed of a GaAs fluoride.

The first substrate may include the semiconductor layer and the first DBR layer formed by crystal growth on a base material formed of GaAs, and

the second substrate may include the constriction layer and the second DBR layer formed by crystal growth on a base material formed of GaAs.

The active layer may have a quantum well structure in which a barrier layer formed of GaAs and a quantum well layer formed of InGaAs are alternately laminated.

The first substrate may include the semiconductor layer and the first DBR layer formed by crystal growth on a base material formed of GaAs, and

the second substrate may include the constriction layer and the second DBR layer formed by crystal growth on a base material formed of InP.

The active layer may have a quantum well structure in which a barrier layer formed of InP and a quantum well layer formed of InGaAs, InGaAsP, or AlGaInAs are alternately laminated.

The first DBR layer may be a semiconductor DBR or a dielectric DBR, and

the second DBR layer may be a semiconductor DBR or a dielectric DBR.

The vertical cavity surface emitting laser element may emit a laser beam from a side of the second DBR layer.

The vertical cavity surface emitting laser element may emit a laser beam from a side of the first DBR layer.

In order to achieve the above-mentioned object, a vertical cavity surface emitting laser element array according to an embodiment of the present technology includes: a plurality of arranged vertical cavity surface emitting laser elements each including a first substrate that is provided with a semiconductor layer including an active layer and a first distributed Bragg reflector (DBR) layer, and a second substrate that is provided with a constriction layer and a second DBR layer, the constriction layer having a constriction region and an injection region having conductivity higher than that of the constriction region, the second substrate being bonded to the first substrate such that the constriction layer is adjacent to the semiconductor layer.

In order to achieve the above-mentioned object, a vertical cavity surface emitting laser module according to an embodiment of the present technology includes: a circuit substrate; and a vertical cavity surface emitting laser element.

The vertical cavity surface emitting laser element includes a first substrate that is provided with a semiconductor layer including an active layer and a first distributed Bragg reflector (DBR) layer, and a second substrate that is provided with a constriction layer and a second DBR layer, the constriction layer having a constriction region and an injection region having conductivity higher than that of the constriction region, the second substrate being bonded to the first substrate such that the constriction layer is adjacent to the semiconductor layer, and is mounted on the circuit substrate.

In order to achieve the above-mentioned object, a method of producing a vertical cavity surface emitting laser module according to an embodiment of the present technology includes:

forming a first substrate that is provided with a semiconductor layer including an active layer and a first distributed Bragg reflector (DBR) layer;

forming a second substrate that is provided with a constriction layer and a second DBR layer, the constriction layer having a constriction region and an injection region having conductivity higher than that of the constriction region; and

bonding the first substrate and the second substrate to each other such that the constriction layer is adjacent to the semiconductor layer.

The step of forming the second substrate may further include forming the constriction region and the injection region using photolithography.

### BRIEF DESCRIPTION OF DRAWINGS

FIG. 1 is a cross-sectional view of a VCSEL element according to a first embodiment of the present technology.

FIG. 2 is a cross-sectional view of a partial configuration of the VCSEL element.

FIG. 3 is a plan view of a constriction layer of the VCSEL element.

FIG. 4 is a schematic diagram showing a method of producing the VCSEL element.

FIG. 5 is a schematic diagram showing a method of producing the VCSEL element.

FIG. 6 is a schematic diagram showing a method of producing the VCSEL element.

FIG. 7 is a schematic diagram showing a method of producing the VCSEL element.

FIG. 8 is a schematic diagram showing a method of producing the VCSEL element.

FIG. 9 is a schematic diagram showing a method of producing the VCSEL element.

FIG. 10 is a cross-sectional view of a VCSEL element according to a second embodiment of the present technology.

FIG. 11 is a cross-sectional view of a VCSEL element according to a third embodiment of the present technology.

FIG. 12 is a cross-sectional view of a VCSEL element according to a fourth embodiment of the present technology.

FIG. 13 is a cross-sectional view of a VCSEL element according to a fifth embodiment of the present technology.

FIG. 14 is a cross-sectional view of a VCSEL element according to a sixth embodiment of the present technology.

FIG. 15 is a cross-sectional view of a VCSEL element array according to a seventh embodiment of the present technology.

FIG. 16 is a cross-sectional view of a VCSEL module according to an eighth embodiment of the present technology.

### MODE(S) FOR CARRYING OUT THE INVENTION

A vertical cavity surface emitting laser (VCSEL) element according to an embodiment of the present technology will be described.

[Structure of VCSEL Element]

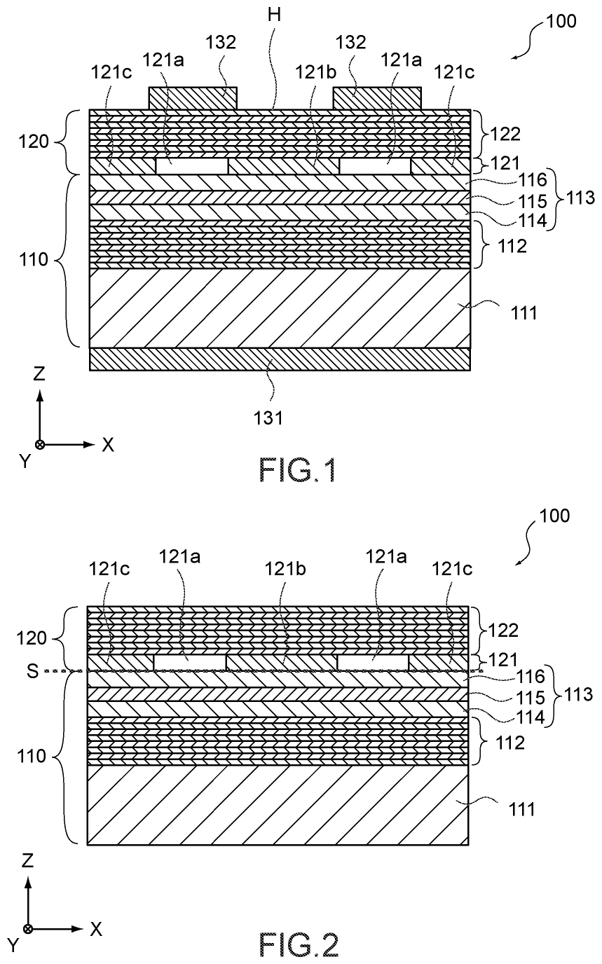

FIG. 1 is a cross-sectional view of a VCSEL element 100 according to this embodiment. As shown in the figure, the VCSEL element 100 includes a first substrate 110 and a second substrate 120. Further, a first electrode 131 is provided on the first substrate 110, and a second electrode 132 is provided on the second substrate 120.

FIG. 2 is a cross-sectional view showing only the first substrate 110 and the second substrate 120. As shown in the figure, the first substrate 110 and the second substrate 120 are bonded to each other on a bonding surface S.

The first substrate 110 includes a base material 111, a first DBR layer 112, and a semiconductor layer 113. The base material 111 supports the respective layers of the VCSEL element 100. The base material 111 can be formed of, for example, n-GaAs, but may be formed of another material.

The first DBR layer 112 is a first reflector, and functions as a distributed Bragg reflector (DBR) that is provided on the base material 111 and reflects light having a wavelength λ. The first DBR layer 112 can be a laminate of a plurality of layers obtained by alternately laminating a low-refractive index layer and a high-refractive index layer. The first DBR layer 112 can be, for example, a semiconductor DBR, the low-refractive index layer can be formed of, for example, AlGaAs, and the high-refractive index layer can be formed of, for example, GaAs. The thickness of each of the low-refractive index layer and the high-refractive index layer is suitably λ/4.

The semiconductor layer 113 includes a first cladding layer 114, an active layer 115, and a second cladding layer 116. The first cladding layer 114 is a layer that is provided on the first DBR layer 112 and confines light and a current in the active layer 115. The first cladding layer 114 is formed of, for example, GaAs.

The active layer 115 is provided on the first cladding layer 114, and emits and amplifies spontaneously emitted light. The active layer 115 can have a multi quantum well (MQW) structure in which a quantum well layer and a barrier layer are alternately laminated, the quantum well layer can be formed of, for example, InGaAs or InAs, and the barrier layer can be formed of, for example, GaAs. Further, the active layer 115 does not necessarily need to have a quantum well structure and may have a quantum dot structure or the like.

The second cladding layer 116 is a layer that is provided on the active layer 115 and confines light and a current in the active layer 115. The second cladding layer 116 is formed of, for example, GaAs. Note that the configuration of the semiconductor layer 113 is not limited to the one shown here, and the semiconductor layer 113 only needs to include at least the active layer 115 without including one or both of the first cladding layer 114 and the second cladding layer 116.

The first DBR layer 112 and the semiconductor layer 113 can be formed by epitaxial crystal growth on the base material 111 formed of GaAs. The material of each of the first DBR layer 112 and the semiconductor layer 113 can be formed by epitaxial crystal growth on the base material 111 formed of GaAs.

The second substrate 120 includes a constriction layer 121 and a second DBR layer 122. The second substrate 120 is bonded to the first substrate 110 such that the constriction layer 121 is adjacent to the semiconductor layer 113 of the first substrate 110.

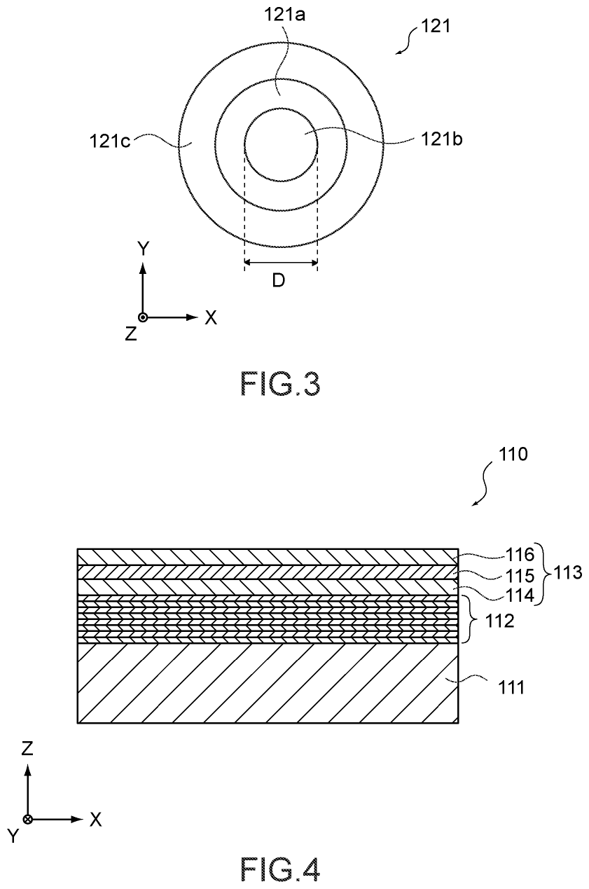

The constriction layer 121 is provided on the semiconductor layer 113 and imparts a constriction action to a current. As shown in FIG. 1, the constriction layer 121 has a constriction region 121a, an injection region 121b, and an outer peripheral region 121c. FIG. 3 is a diagram of the constriction layer 121 as viewed from a direction (Z direction) perpendicular to the layer surface. As shown in the figure, the injection region 121b is provided in the central portion of the constriction layer 121, and the constriction region 121a is formed in a ring shape surrounding the injection region 121b. The outer peripheral region 121c is provided on the outer periphery of the constriction region 121a.

The constriction region 121a is a region having conductivity lower than that of the injection region 121b. As shown in FIG. 1, the constriction region 121a can be a gap.

The injection region 121b is a region having conductivity higher than that of the constriction region 121a. Further, the injection region 121b is suitably formed of a material having a refractive index larger than that of the constriction region 121a. The injection region 121b can be formed of, for example, GaAs. As shown in FIG. 3, the injection region 121b can have a circular shape as viewed from the Z direction. Further, the shape of the injection region 121b is not limited to a circular shape, and the injection region 121b may have a rectangular shape or another shape.

The outer peripheral region 121c can be formed of the same material as that of the injection region 121b. Further, the outer peripheral region 121c does not necessarily need to be provided, and the constriction region 121a may be formed from the peripheral edge of the injection region 121b to the end face of the VCSEL element 100.

The second DBR layer 122 is a second reflector, and functions as a DBR that is provided on the constriction layer 121 and reflects light having the wavelength λ. The second DBR layer 122 can be a laminate of a plurality of layers obtained by alternately laminating a low-refractive index layer and a high-refractive index layer. The second DBR layer 122 can be, for example, a semiconductor DBR, the low-refractive index layer can be formed of, for example, AlGaAs, and the high-refractive index layer can be formed of, for example, GaAs. The thickness of each of the low-refractive index layer and the high-refractive index layer is suitably λ/4.

The constriction layer 121 and the second DBR layer 122 can be formed by epitaxial crystal growth on a base material formed of GaAs, which is used in a production process. The material of each of the constriction layer 121 and the second DBR layer 122 can be formed by epitaxial crystal growth on a base material formed of GaAs.

The first electrode 131 is formed of a conductive material and is provided on the base material 111. The first electrode 131 can be obtained by, for example, laminating an AuGe layer, a Ni layer, and an Au layer in this order from the side of the base material 111.

The second electrode 132 is formed of a conductive material and is provided on the second DBR layer 122. The second electrode 132 can have an annular shape centered on the injection region 121b as viewed from the Z direction. The second electrode 132 can be obtained by, for example, a Ti layer, a Pt layer, and an Au layer in this order from the side of the second DBR layer 122.

The VCSEL element 100 has the configuration as described above. Note that the material of each layer is not limited to the above-mentioned one, and an arbitrary material may be used as long as the VCSEL element 100 is capable of operating. Also the shape and the thickness of each layer can be appropriately adjusted.

[Operation of VCSEL Element]

When a voltage is applied between the first electrode 131 and the second electrode 132, a current flows between the first electrode 131 and the second electrode 132. The current is subjected to a constriction action (current confinement action) in the constriction layer 121 and is injected into the injection region 121b.

This injected current generates spontaneously emitted light in a region of the active layer 115 close to the injection region 121b. The spontaneously emitted light travels in the lamination direction (Z direction) of the VCSEL element 100 and is reflected by the first DBR layer 112 and the second DBR layer 122.

The first DBR layer 112 and the second DBR layer 122 are configured to reflect light having the oscillation wavelength λ. Of the spontaneously emitted light, the component having the oscillation wavelength λ forms a standing wave between the first DBR layer 112 and the second DBR layer 122 and is amplified by the active layer 115.

When the injected current exceeds a threshold value, the light forming a standing wave performs laser oscillation, and a laser beam is emitted through the second cladding layer 116, the constriction layer 121, and the second DBR layer 122. In FIG. 1, the surface through which a laser beam is emitted is shown as a light emission surface H.

Note that of the light generated in the active layer 115, the light that has entered the interface between the injection region 121b and the constriction region 121a is refracted toward the injection region 121b due to the refractive index difference between the two regions, and contributes to laser oscillation. That is, the constriction layer 121 has the light confinement action in addition to the current confinement action.

As described above, the current is subjected to a confinement action by the constriction region 121a and injected into the active layer 115. For this reason, the shape of the constriction region 121a is required to have a certain degree of accuracy or higher. If the shape accuracy of the constriction region 121a is low, the optical aperture (OA) diameter (diameter D in FIG. 3) varies from that of another VCSEL element 100, and the beam properties of a laser beam to be emitted are affected.

Here, as will be described below, the VCSEL element 100 is configured so that the constriction region 121a can be prepared with high accuracy and the OA diameter can be prevented from varying. Further, in the VCSEL element 100, since the constriction layer 121 is provided between the first DBR layer 112 and the second DBR layer 122, the current confinement property of the constriction layer 121 is high.

Further, in the VCSEL element 100, the constriction region 121a can be formed as a gap. As a result, it is possible to make the refractive index difference large between the injection region 121b and the constriction region 121a and make the light confinement property by the constriction layer 121 high.

[Method of Producing VCSEL Element]

A method of producing the VCSEL element 100 will be described. FIG. 4 to FIG. 9 are each a schematic diagram showing a method of producing the VCSEL element 100.

As shown in FIG. 4, the first substrate 110 is prepared. The first substrate 110 can be prepared by laminating the first DBR layer 112 and the semiconductor layer 113 by crystal growth on the base material 111. The crystal growth can be, for example, epitaxial crystal growth.

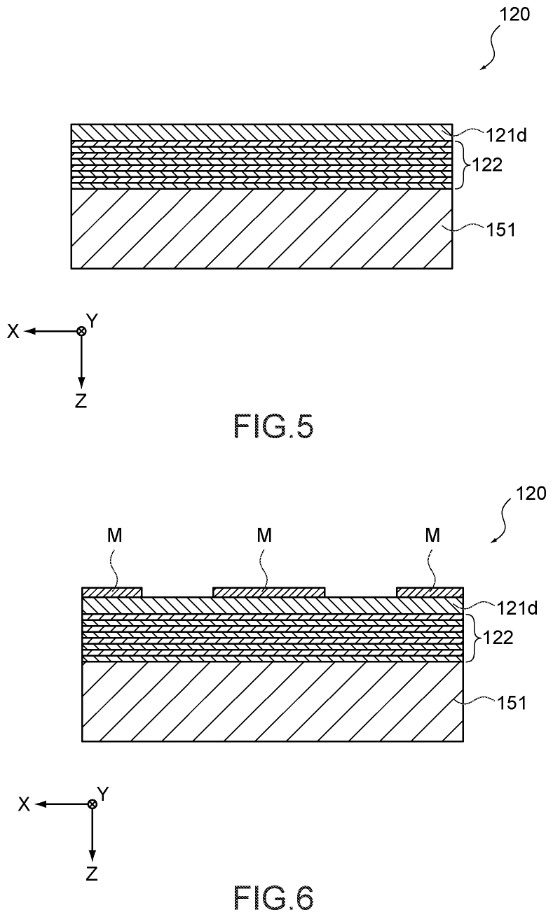

Subsequently, the second substrate 120 is prepared. In the process of preparing the second substrate 120, the second DBR layer 122 and a constriction layer 121d are laminated by crystal growth on the base material 151 as shown in FIG. 5. The crystal growth can be, for example, epitaxial crystal growth. The base material 151 can be formed of, for example, n-GaAs, but may be formed of another material.

Subsequently, as shown in FIG. 6, an etching mask M having a predetermined opening is formed on the constriction layer 121d. The etching mask M may be a photomask patterned by photolithography or may be a hard mask or a metal mask formed by laser drawing or the like.

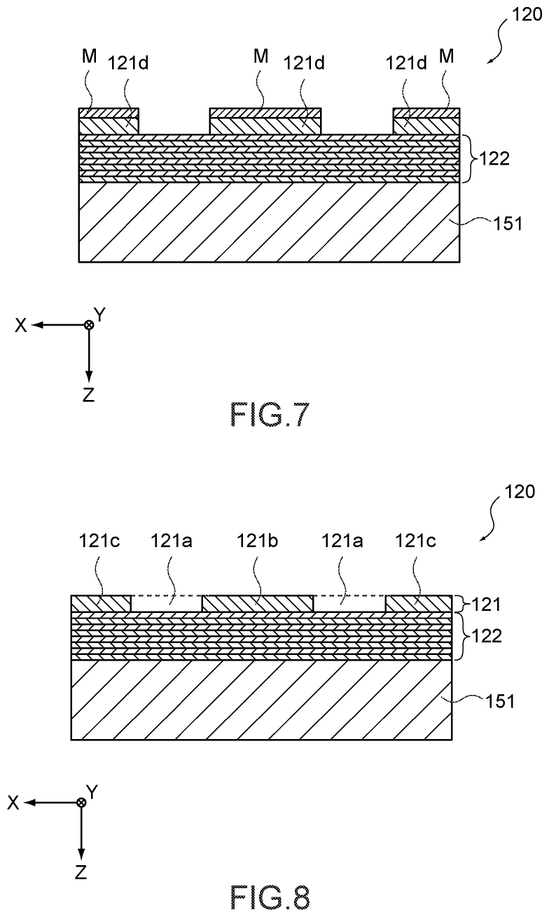

Subsequently, as shown in FIG. 7, the constriction layer 121d is etched using the etching mask M to remove part of the constriction layer 121d. For example, wet etching using an aqueous citric acid solution as an etching solution can be performed. Further, in this step, dry etching may be used.

Subsequently, as shown in FIG. 8, the mask M is removed. By this etching step, the constriction layer 121 having the constriction region 121a, the injection region 121b, and the outer peripheral region 121c is formed.

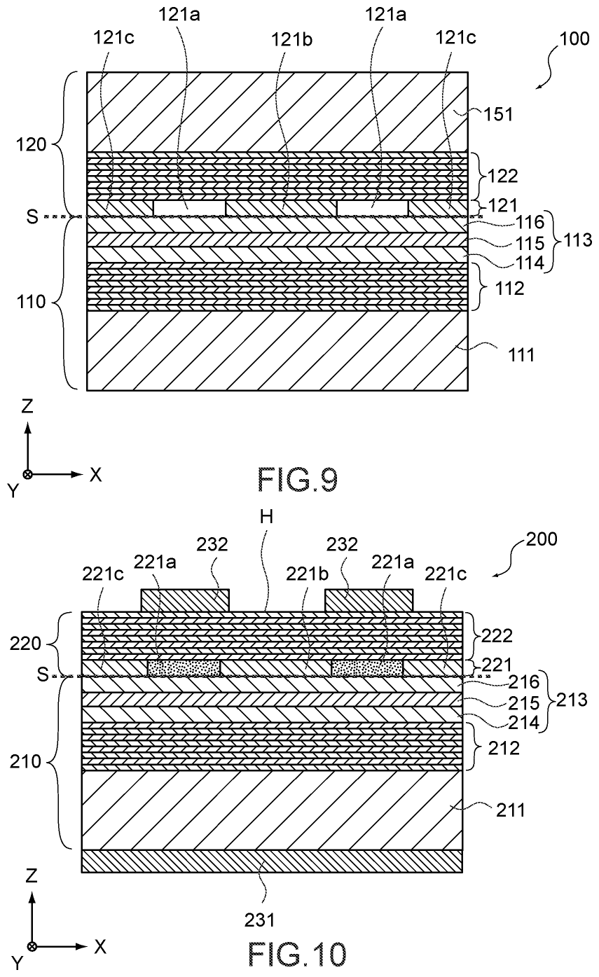

Subsequently, as shown in FIG. 9, the first substrate 110 and the second substrate 120 are bonded to each other. In the figure, the bonding surface between the first substrate 110 and the second substrate 120 is shown as the bonding surface S. This bonding method is not particularly limited, and an arbitrary bonding method such as room temperature bonding, plasma bonding, and thermal diffusion bonding can be used.

Subsequently, the base material 151 is removed to form the structure shown in FIG. 2. The base material 151 can be removed by grinding or etching. Subsequently, as shown in FIG. 1, the first electrode 131 and the second electrode 132 are formed. These electrodes can be formed by vapor deposition. Further, annealing is performed after vapor deposition to generate an ohmic contact.

The VCSEL element 100 can be produced in this way. As described above, in the VCSEL element 100, the constriction region 121a is removed by etching to form a constriction structure. In the etching, a constriction structure can be formed with high accuracy using photolithography or the like, and a VCSEL element whose pitch can be narrowed to 10 μm or less can be realized. Further, in the VCSEL element 100, since it is unnecessary to form a mesa (plateau-like structure) unlike the existing oxidization constriction process and a planar VCSEL structure can be obtained, the mesa forming step is unnecessary and the production step can be simplified.

### Second Embodiment

A VCSEL element according to a second embodiment of the present technology will be described.

[Structure of VCSEL Element]

FIG. 10 is a cross-sectional view of a VCSEL element 200 according to this embodiment. As shown in the figure, the VCSEL element 200 includes a first substrate 210 and a second substrate 220. Further, a first electrode 231 is provided on the first substrate 210, and a second electrode 232 is provided on the second substrate 220.

The first substrate 210 includes a base material 211, a first DBR layer 212, and a semiconductor layer 213. The first substrate 210 has the same configuration as that of the first substrate 110 according to the first embodiment. That is, the base material 211 has the same configuration as that of the base material 111, and the first DBR layer 212 has the same configuration as that of the first DBR layer 112. Further, the semiconductor layer 213 has the same configuration as that of the semiconductor layer 113, and a first cladding layer 214, an active layer 215, and a second cladding layer 216 respectively have the same configurations as those of the first cladding layer 114, the active layer 115, and the second cladding layer 116.

The second substrate 220 includes a constriction layer 221 and a second DBR layer 222. The second substrate 220 is bonded to the first substrate 210 such that the constriction layer 221 is adjacent to the semiconductor layer 213 of the first substrate 210. In FIG. 10, the bonding surface between the first substrate 210 and the second substrate 220 is shown as the bonding surface S.

The constriction layer 221 is provided on the semiconductor layer 213 and imparts a constriction action to a current. As shown in FIG. 10, the constriction layer 221 has a constriction region 221a, an injection region 221b, and an outer peripheral region 221c. The injection region 221b is provided in the central portion of the constriction layer 221, and the constriction region 221a is formed in a ring shape surrounding the injection region 221b. The outer peripheral region 221c is provided on the outer periphery of the constriction region 221a.

The constriction region 221a is a region having conductivity lower than that of the injection region 221b. For example, the injection region 221b and the outer peripheral region 221c are each formed of a predetermined conductive material, and the constriction region 221a can be formed of a material obtained by applying non-conductive treatment to this conductive material.

The injection region 221b is a region having conductivity higher than that of the constriction region 221a. Further, the injection region 221b is suitably formed of a material having a refractive index larger than that of the constriction region 221a. The injection region 221b can have a circular shape as viewed from the Z direction. Further, the shape of the injection region 221b is not limited to a circular shape, and the injection region 221b may have a rectangular shape or another shape.

The outer peripheral region 221c can be formed of the same material as that of the injection region 221b. Further, the outer peripheral region 221c does not necessarily need to be provided, and the constriction region 221a may be formed from the peripheral edge of the injection region 221b to the end surface of the VCSEL element 200.

Specifically, the injection region 221b and the outer peripheral region 221c can each be a layer formed of GaAs, and the constriction region 221a can be a layer formed of a material obtained by applying fluorine treatment to GaAs. The constriction region 221a can be formed with high accuracy by using a mask (see FIG. 6) in which an opening corresponding to the constriction region 221a is provided.

Further, the constriction region 221a can be formed of a predetermined non-conductive material, and the injection region 221b and the outer peripheral region 221c can each be formed of a material obtained by applying conductive treatment to this non-conductive material. The conductive treatment is, for example, doping. The injection region 221b and the outer peripheral region 221c can each formed with high accuracy by using a mask in which openings corresponding to these regions is provided.

The second DBR layer 222 is provided on the constriction layer 221 and functions as a DBR that reflects light having the wavelength λ. The second DBR layer 222 has the same configuration as that of the second DBR layer 122 according to the first embodiment.

The first electrode 231 is formed of a conductive material and is provided on the base material 211. The first electrode 231 can be obtained by, for example, laminating an AuGe, a Ni layer, and an Au layer in this order from the side of the base material 211.

The second electrode 232 is formed of a conductive material and is provided on the second DBR layer 222. The second electrode 232 can have an annular shape centered on the injection region 221b as viewed from the Z direction. The second electrode 232 can be obtained by, for example, laminating a Ti layer, a Pt layer, and an Au layer in this order from the side of the second DBR layer 222.

The VCSEL element 200 has the configuration as described above. Note that the material of each layer is not limited to the above-mentioned one, and an arbitrary material may be used as long as the VCSEL element 200 is capable of operating. Also the shape and the thickness of each layer can be appropriately adjusted.

[Operation of VCSEL Element]

The VCSEL element 200 operates in the same way as the VCSEL element 100 according to the first embodiment. In the VCSEL element 200, the constriction region 221a can be prepared with high accuracy and the OA diameter can be prevented from varying. Further, in the VCSEL element 200, by forming the constriction region 221a as a region where a material exists instead of a gap, the constriction layer 221 easily transfers heat and heat dissipation can be improved.

[Method of Producing VCSEL Element]

The VCSEL element 200 can be prepared by preparing the first substrate 210 and the second substrate 220 and bonding both the substrates to each other, similarly to the first embodiment. The constriction layer 221 can be formed using a mask that can be formed with high accuracy by photolithography or the like, and the pitch of the VCSEL element 200 can be narrowed.

### Third Embodiment

A VCSEL element according to a third embodiment of the present technology will be described.

[Structure of VCSEL Element]

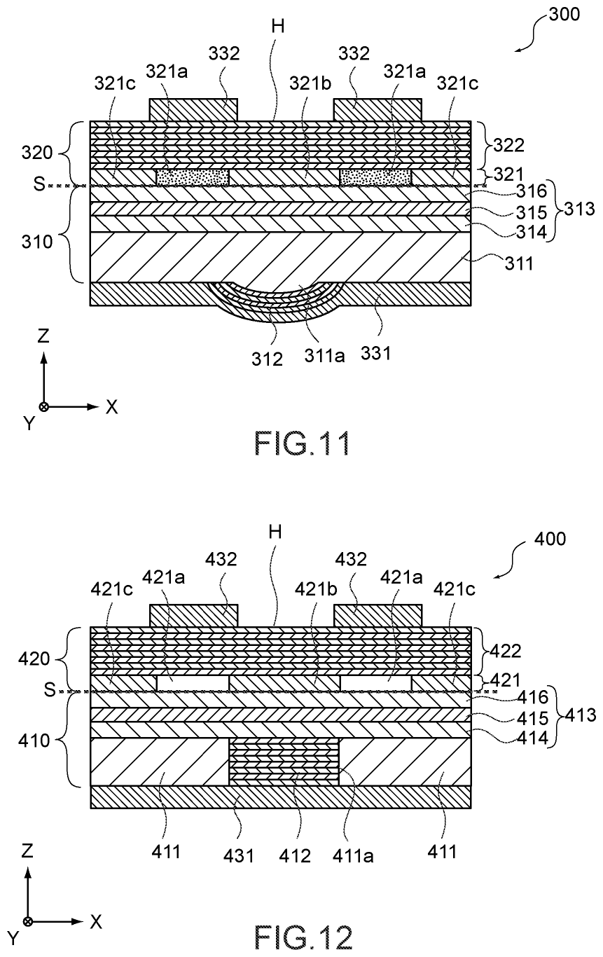

FIG. 11 is a cross-sectional view of a VCSEL element 300 according to this embodiment. As shown in the figure, the VCSEL element 300 includes a first substrate 310 and a second substrate 320. Further, a first electrode 331 is provided on the first substrate 310, and a second electrode 332 is provided on the second substrate 320.

The first substrate 310 includes a base material 311, a first DBR layer 312, and a semiconductor layer 313. The base material 311 supports the respective layers of the VCSEL element 300. The base material 311 can be formed of, for example, n-GaAs, but may be formed of another material. A projecting portion 311a having a lens shape is provided on the surface of the base material 311 opposite to the semiconductor layer 313. The shape of the projecting portion 311a may be a spherical lens shape, a cylindrical lens shape, or another lens shape.

The first DBR layer 312 is provided on the projecting portion 311a and functions as a DBR that reflects light having the wavelength λ. Each layer of the first DBR layer 312 is curved along the shape of the projecting portion 311a to form a lens. The first DBR layer 312 can be a laminate of a plurality of layers obtained by alternately laminating a low-refractive index layer and a high-refractive index layer. The low-refractive index layer is formed of, for example, AlGaAs and the high-refractive index layer is formed of, for example, GaAs. The thickness of each of the low-refractive index layer and the high-refractive index layer is suitably λ/4.

The semiconductor layer 313 includes a first cladding layer 314, an active layer 315, and a second cladding layer 316. The first cladding layer 314 is a layer that is provided on the base material 311 and confines light and a current in the active layer 315. The first cladding layer 314 is formed of, for example, GaAs.

The active layer 315 is provided on the first cladding layer 314 and emits and amplifies spontaneously emitted light. The active layer 315 has a multi-quantum well structure in which a quantum well layer and a barrier layer are alternately laminated, the quantum well layer can be formed of, for example, InGaAs, and the barrier layer can be formed of, for example, GaAs. Further, the active layer 315 does not necessarily need to have a quantum well structure and may have a quantum dot structure or the like.

The second cladding layer 316 is a layer that is provided on the active layer 315 and confines light and a current in the active layer 315. The second cladding layer 316 is formed of, for example, GaAs. Note that the configuration of the semiconductor layer 313 is not limited to the one shown here, and the semiconductor layer 313 only needs to include at least the active layer 315 without including one or both of the first cladding layer 314 and the second cladding layer 316.

The second substrate 320 includes a constriction layer 321 and a second DBR layer 322. The second substrate 320 is bonded to the first substrate 310 such that the constriction layer 321 is adjacent to the semiconductor layer 313 of the first substrate 310. In FIG. 11, the bonding surface between the first substrate 310 and the second substrate 320 is shown as the bonding surface S.

The second substrate 320 has the same configuration as that of the second substrate 220 according to the second embodiment. That is, the constriction layer 321 has a constriction region 321a, an injection region 321b, and an outer peripheral region 321c, and these respectively have the same configurations as those of the constriction region 221a, the injection region 221b, and the outer peripheral region 221c. Further, the second DBR layer 322 has the same configuration as that of the second DBR layer 222.

The first electrode 331 is formed of a conductive material and is provided on the base material 311 and the first DBR layer 312. The first electrode 331 can be obtained by, for example, laminating an AuGe layer, a Ni layer, and an Au layer in this order from the side of the base material 311.

The second electrode 332 is formed of a conductive material and is provided on the second DBR layer 322. The second electrode 332 can have an annular shape centered on the injection region 321b as viewed from the Z direction. The second electrode 332 can be obtained by, for example, laminating a Ti layer, a Pt layer, and an Au layer in this order from the side of the second DBR layer 322.

The VCSEL element 300 has the configuration as described above. Note that the material of each layer is not limited to the above-mentioned one, and an arbitrary material may be used as long as the VCSEL element 300 is capable of operating. Also the shape and the thickness of each layer can be appropriately adjusted.

[Operation of VCSEL Element]

The VCSEL element 300 operates in the same way as the VCSEL element 100 according to the first embodiment. In the VCSEL element 300, the constriction region 321a can be prepared with high accuracy and the OA diameter can be prevented from varying. Further, in the VCSEL element 300, by forming the constriction region 321a as a region where a material exists instead of a gap, the constriction layer 321 easily transfers heat and heat dissipation can be improved.

Further, in the VCSEL element 300, by providing a lens structure on the base material 311, light that enters the base material 311 from the side of the semiconductor layer 313 is collected on the injection region 321b by the first DBR layer 312 having a lens shape, and the light confinement property can be improved. For this reason, even in the case where the refractive index difference between the constriction region 321a and the injection region 321b is small, a high light confinement property can be achieved.

[Method of Producing VCSEL Element]

The VCSEL element 300 can be prepared by preparing the first substrate 310 and the second substrate 320 and bonding both the substrates to each other, similarly to the first embodiment. The constriction layer 321 can be formed using a mask that can be formed with high accuracy by photolithography or the like, and the pitch of the VCSEL element 300 can be narrowed.

### Fourth Embodiment

A VCSEL element according to a fourth embodiment of the present technology will be described.

[Structure of VCSEL Element]

FIG. 12 is a cross-sectional view of a VCSEL element 400 according to this embodiment. As shown in the figure, the VCSEL element 400 includes a first substrate 410 and a second substrate 420. Further, a first electrode 431 is provided on the first substrate 410, and a second electrode 432 is provided on the second substrate 420.

The first substrate 410 includes a base material 411, a first DBR layer 412, and a semiconductor layer 413. The base material 411 supports the respective layers of the VCSEL element 400. The base material 411 can be formed of, for example, n-GaAs, but may be formed of another material. As shown in FIG. 12, in the base material 411, an opening 411a is provided at a position corresponding to an injection region 421b.

The first DBR layer 412 is provided inside the opening 411a and functions as a DBR that reflects light having the wavelength λ. The first DBR layer 412 can be a laminate of a plurality of layers obtained by alternately laminating a low-refractive index layer and a high-refractive index layer. The first DBR layer 412 can be, for example, a dielectric DBR, the low-refractive index layer can be formed of, for example, SiO₂, and the high-refractive index layer can be formed of, for example, Ta₂O₅. The thickness of each of the low-refractive index layer and the high-refractive index layer is suitably λ/4.

The semiconductor layer 413 includes a first cladding layer 414, an active layer 415, and a second cladding layer 416. The first cladding layer 414 is a layer that is provided on the base material 411 and the first DBR layer 412 and confines light and a current in the active layer 415. The first cladding layer 414 is formed of, for example, GaAs.

The active layer 415 is provided on the first cladding layer 414 and emits and amplifies spontaneously emitted light. The active layer 415 has a multi-quantum well structure in which a quantum well layer and a barrier layer are alternately laminated, the quantum well layer can be formed of, for example, InGaAs, and the barrier layer can be formed of, for example, GaAs. Further, the active layer 415 does not necessarily need to have a quantum well structure and may have a quantum dot structure or the like.

The second cladding layer 416 is a layer that is provided on the active layer 415 and confines light and a current in the active layer 415. The second cladding layer 416 is formed of, for example, GaAs. Note that the configuration of the semiconductor layer 413 is not limited to the one shown here, and the semiconductor layer 413 only needs to include at least the active layer 415 without including one or both of the first cladding layer 414 and the second cladding layer 416.

The second substrate 420 includes a constriction layer 421 and a second DBR layer 422. The second substrate 420 is bonded to the first substrate 410 such that the constriction layer 421 is adjacent to the semiconductor layer 413 of the first substrate 410. In FIG. 12, the bonding surface between the first substrate 410 and the second substrate 420 is shown as the bonding surface S.

The second substrate 420 has the same configuration as that of the second substrate 120 according to the first embodiment. That is, the constriction layer 421 has a constriction region 421a, the injection region 421b, and an outer peripheral region 421c, and these respectively have the same configurations as those of the constriction region 121a, the injection region 121b, and the outer peripheral region 121c. Further, the second DBR layer 422 has the same configuration as that of the second DBR layer 122.

The first electrode 431 is formed of a conductive material and is provided on the base material 411 and the first DBR layer 412. The first electrode 431 can be obtained by, for example, laminating an AuGe layer, a Ni layer, and an Au layer in this order from the side of the base material 311.

The second electrode 432 is formed of a conductive material and is provided on the second DBR layer 422. The second electrode 432 can have an annular shape centered on the injection region 421b as viewed from the Z direction. The second electrode 432 can be obtained by, for example, laminating a Ti layer, a Pt layer, and an Au layer in this order from the side of the second DBR layer 422.

The VCSEL element 400 has the configuration as described above. Note that the material of each layer is not limited to the above-mentioned one, and an arbitrary material may be used as long as the VCSEL element 400 is capable of operating. Also the shape and the thickness of each layer can be appropriately adjusted. For example, although the first DBR layer 412 has been a dielectric DBR and the second DBR layer 422 has been a semiconductor DBR in the VCSEL element 400, the first DBR layer 412 may be a semiconductor DBR and the second DBR layer 422 may be a dielectric DBR or both of them may each be a dielectric DBR.

[Operation of VCSEL Element]

The VCSEL element 400 operates in the same way as the VCSEL element 100 according to the first embodiment. In the VCSEL element 400, the constriction region 421a can be prepared with high accuracy and the OA diameter can be prevented from varying.

[Method of Producing VCSEL Element]

The VCSEL element 400 can be prepared by preparing the first substrate 410 and the second substrate 420 and bonding both the substrates to each other, similarly to the first embodiment. The constriction layer 421 can be formed using a mask that can be formed with high accuracy by photolithography or the like, and the pitch of the VCSEL element 400 can be narrowed.

### Fifth Embodiment

A VCSEL element according to a fifth embodiment of the present technology will be described.

[Structure of VCSEL Element]

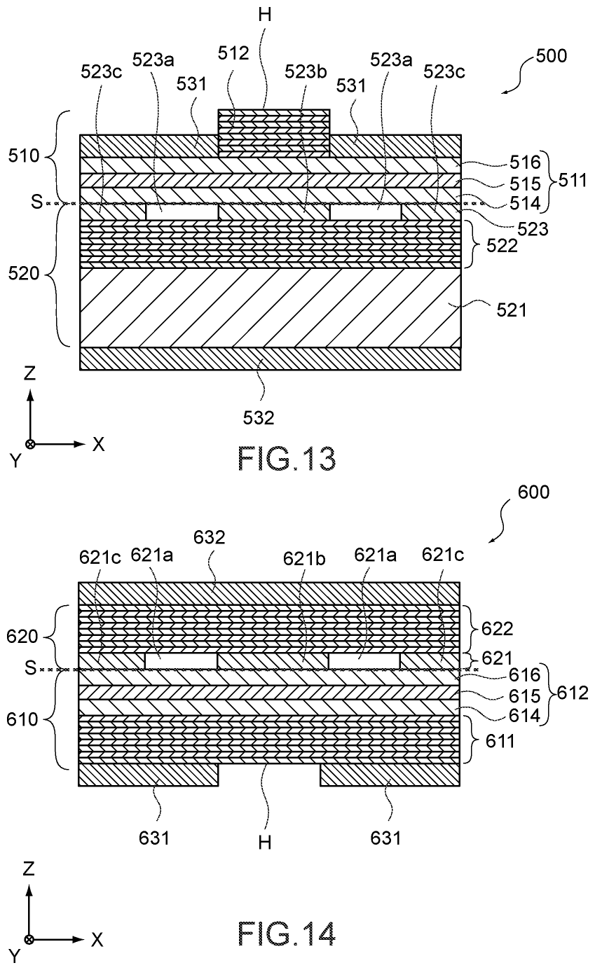

FIG. 13 is a cross-sectional view of a VCSEL element 500 according to this embodiment. As shown in the figure, the VCSEL element 500 includes a first substrate 510 and a second substrate 520. Further, a first electrode 531 is provided on the first substrate 510, and a second electrode 532 is provided on the second substrate 520.

The first substrate 510 includes a semiconductor layer 511 and a first DBR layer 512. The semiconductor layer 511 includes a first cladding layer 514, an active layer 515, and a second cladding layer 516. The first cladding layer 514 is a layer that confines light and a current in the active layer 515. The first cladding layer 514 is formed of, for example, InP.

The active layer 515 is provided on the first cladding layer 514 and emits and amplifies spontaneously emitted light. The active layer 515 has a multi quantum well (MQW) structure in which a quantum well layer and a barrier layer are alternately laminated, the quantum well layer can be formed of, for example, InGaAs, InGaAsP, or AlGaInAs, and the barrier layer can be formed of, for example, InP. Further, the active layer 515 does not necessarily need to have a quantum well structure and may have a quantum dot structure or the like.

The second cladding layer 516 is a layer that is provided on the active layer 515 and confines light and a current in the active layer 515. The second cladding layer 516 is formed of, for example, InP. Note that the configuration of the semiconductor layer 511 is not limited to the one shown here, and the semiconductor layer 511 only needs to include at least the active layer 515 without including one or both of the first cladding layer 514 and the second cladding layer 516.

The first DBR layer 512 is provided on the semiconductor layer 511 and functions as a DBR that reflects light having the wavelength λ. The first DBR layer 512 can be a laminate of a plurality of layers obtained by alternately laminating a low-refractive index layer and a high-refractive index layer. The first DBR layer 512 can be, for example, a dielectric DBR, the low-refractive index layer can be formed of, for example, SiO₂, and the high-refractive index layer can be formed of, for example, Ta₂O₅. The thickness of each of the low-refractive index layer and the high-refractive index layer is suitably λ/4.

The first DBR layer 512 and the semiconductor layer 511 can each be formed by epitaxial growth on a base material formed of InP, which is used in a production process. The material of each of the first DBR layer 512 and the semiconductor layer 511 can be formed by epitaxial crystal growth on a base material formed of InP.

The second substrate 520 includes a base material 521, a second DBR layer 522, and a constriction layer 523. The second substrate 520 is bonded to the first substrate 510 such that the constriction layer 523 is adjacent to the semiconductor layer 511 of the first substrate 510. In FIG. 13, the bonding surface between the first substrate 510 and the second substrate 520 is shown as the bonding surface S.

The base material 521 supports the respective layers of the VCSEL element 500. The base material 521 can be formed of, for example, n-GaAs, but may be formed of another material.

The second DBR layer 522 is provided on the base material 521 and functions as a DBR that reflects light having the wavelength λ. The second DBR layer 522 can be a laminate of a plurality of layers obtained by alternately laminating a low-refractive index layer and a high-refractive index layer. The second DBR layer 522 can be formed of, for example, a semiconductor DBR, the low-refractive index layer can be formed of, for example, AlGaAs, and the high-refractive index layer can be formed of, for example, GaAs. The thickness of each of the low-refractive index layer and the high-refractive index layer is suitably λ/4.

The constriction layer 523 is provided on the second DBR layer 522 and imparts a constriction action to a current. As shown in FIG. 13, the constriction layer 523 has a constriction region 523a, an injection region 523b, and an outer peripheral region 523c. The injection region 523b is provided in the central portion of the constriction layer 523, and the constriction region 523aa is formed in a ring shape surrounding the injection region 523b. The outer peripheral region 523c is provided on the outer periphery of the constriction region 523a.

The constriction region 523a is a region having conductivity lower than that of the injection region 523b. As shown in FIG. 13, the constriction region 523a can be formed as a gap. Further, the constriction region 523a may be a region formed of a material having conductivity lower than that of the injection region 523b.

The injection region 523b is a region having conductivity higher than that of the constriction region 523a. Further, the injection region 523b is suitably formed of a material having a refractive index larger than that of the constriction region 523a. The injection region 523b can be formed of, for example, GaAs. The injection region 523b can have a circular shape as viewed from the Z direction. Further, the shape of the injection region 523b is not limited to a circular shape, and the injection region 523b may have a rectangular shape or another shape.

The outer peripheral region 523c can be formed of the same material as that of the injection region 523b. Further, the outer peripheral region 523c does not necessarily need to be provided, and the constriction region 523a may be formed from the peripheral edge of the injection region 523b to the end surface of the VCSEL element 500.

The second DBR layer 522 and the constriction layer 523 can each be formed by epitaxial crystal growth on the base material 521 formed of GaAs. The material of each of the second DBR layer 522 and the constriction layer 523 can be formed by epitaxial crystal growth on the base material 521 formed of GaAs.

The first electrode 531 is formed of a conductive material and is provided on the semiconductor layer 511. The first electrode 531 can have an annular shape centered on the injection region 523b as viewed from the Z direction. The first electrode 531 can be obtained by, for example, laminating a Ti layer, a Pt layer, and an Au layer in this order from the side of the semiconductor layer 511.

The second electrode 532 is formed of a conductive material and is provided on the base material 521. The second electrode 532 can be obtained by, for example, laminating an AuGe layer, a Ni layer, and an Au layer in this order from the side of the base material 521.

The VCSEL element 500 has the configuration as described above. Note that the material of each layer is not limited to the above-mentioned one, and an arbitrary material may be used as long as the VCSEL element 500 is capable of operating. Also the shape and the thickness of each layer can be appropriately adjusted.

Here, since the VCSEL element 500 is formed by bonding the first substrate 51 and the second substrate 520 to each other, the first substrate 510 and the second substrate 520 can be formed of different materials as described above. For example, the first substrate 510 can be formed of an InP material and the second substrate 520 can be formed of a GaAs material.

[Operation of VCSEL Element]

The VCSEL element 500 operates in the same way as the VCSEL element 100 according to the first embodiment. In the VCSEL element 500, the constriction region 523a can be prepared with high accuracy and the OA diameter can be prevented from varying.

[Method of Producing VCSEL Element]

The VCSEL element 500 can be prepared by preparing the first substrate 510 and the second substrate 520 and bonding both the substrates to each other, similarly to the first embodiment. The constriction layer 523 can be formed using a mask that can be formed with high accuracy by photolithography or the like, and the pitch of the VCSEL element 500 can be narrowed.

### Sixth Embodiment

A VCSEL element according to a sixth embodiment of the present technology will be described.

FIG. 14 is a cross-sectional view of a VCSEL element 600 according to this embodiment. As shown in the figure, the VCSEL element 600 includes a first substrate 610 and a second substrate 620. Further, a first electrode 631 is provided on the first substrate 610, and a second electrode 632 is provided on the second substrate 620.

The first substrate 610 includes a first DBR layer 611 and a semiconductor layer 612. The first DBR layer 611 functions as a DBR that reflects light having the wavelength λ. The first DBR layer 611 can be a laminate of a plurality of layers obtained by alternately laminating a low-refractive index layer and a high-refractive index layer. The first DBR layer 611 can be formed of, for example, a semiconductor DBR, the low-refractive index layer can be formed of, for example, AlGaAs, and the high-refractive index layer can be formed of, for example, GaAs. The thickness of each of the low-refractive index layer and the high-refractive index layer is suitably λ/4.

The semiconductor layer 612 includes a first cladding layer 614, an active layer 615, and a second cladding layer 616. The semiconductor layer 612 has the same configuration as that of the semiconductor layer 113 according to the first embodiment. That is, the first cladding layer 614, the active layer 615, and the second cladding layer 616 respectively have the same configuration as those of the first cladding layer 114, the active layer 115, and the second cladding layer 116.

The second substrate 620 includes a constriction layer 621 and a second DBR layer 622. The second substrate 620 is bonded to the first substrate 610 such that the constriction layer 621 is adjacent to the semiconductor layer 612 of the first substrate 610. In FIG. 14, the bonding surface between the first substrate 610 and the second substrate 620 is shown as the bonding surface S.

The constriction layer 621 is provided on the semiconductor layer 612 and imparts a constriction action to a current. The constriction layer 621 has the same configuration as that of the constriction layer 121 according to the first embodiment. That is, the constriction layer 621 has a constriction region 621a, an injection region 621b, and an outer peripheral region 621c, and these respectively have the same configurations as those of the constriction region 121a, the injection region 121b, and the outer peripheral region 121c.

The second DBR layer 622 is provided on the constriction layer 621 and functions as a DBR that reflects light having the wavelength λ. The second DBR layer 622 can be a laminate of a plurality of layers obtained by alternately laminating a low-refractive index layer and a high-refractive index layer. The second DBR layer 622 can be, for example, a semiconductor DBR, the low-refractive index layer can be formed of, for example, AlGaAs, and the high-refractive index layer can be formed of, for example, GaAs. The thickness of each of the low-refractive index layer and the high-refractive index layer is suitably λ/4.

Here, the first DBR layer 611 and the second DBR layer 622 are configured such that a laser beam is emitted toward the first DBR layer 611 (downward in the figure). In FIG. 14, the surface through which a laser beam is emitted is shown as a light emission surface H.

The first electrode 631 is formed of a conductive material and is provided on the first DBR layer 611. The first electrode 631 can have an annular shape centered on the injection region 621b as viewed from the Z direction. The first electrode 631 can be obtained by, for example, laminating an AuGe layer, a Ni layer, and an Au layer in this order from the side of the first DBR layer 611.

The second electrode 632 is formed of a conductive material and is provided on the second DBR layer 622. The second electrode 632 can be obtained by, for example, laminating a Ti layer, a Pt layer, and an Au layer in this order from the side of the second DBR layer 622.

The VCSEL element 600 has the configuration as described above. Note that the material of each layer is not limited to the above-mentioned one, and an arbitrary material may be used as long as the VCSEL element 600 is capable of operating. Also the shape and the thickness of each layer can be appropriately adjusted.

[Operation of VCSEL Element]

The VCSEL element 600 operates in the same way as the VCSEL element 100 according to the first embodiment except for the direction in which a laser beam is emitted. In the VCSEL element 600, the constriction region 621a can be prepared with high accuracy and the OA diameter can be prevented from varying.

[Method of Producing VCSEL Element]

The VCSEL element 600 can be prepared by preparing the first substrate 610 and the second substrate 620 and bonding both the substrates to each other, similarly to the first embodiment. The constriction layer 621 can be formed using a mask that can be formed with high accuracy by photolithography or the like, and the pitch of the VCSEL element 600 can be narrowed.

### Seventh Embodiment

A VCSEL element array according to a seventh embodiment of the present technology will be described.

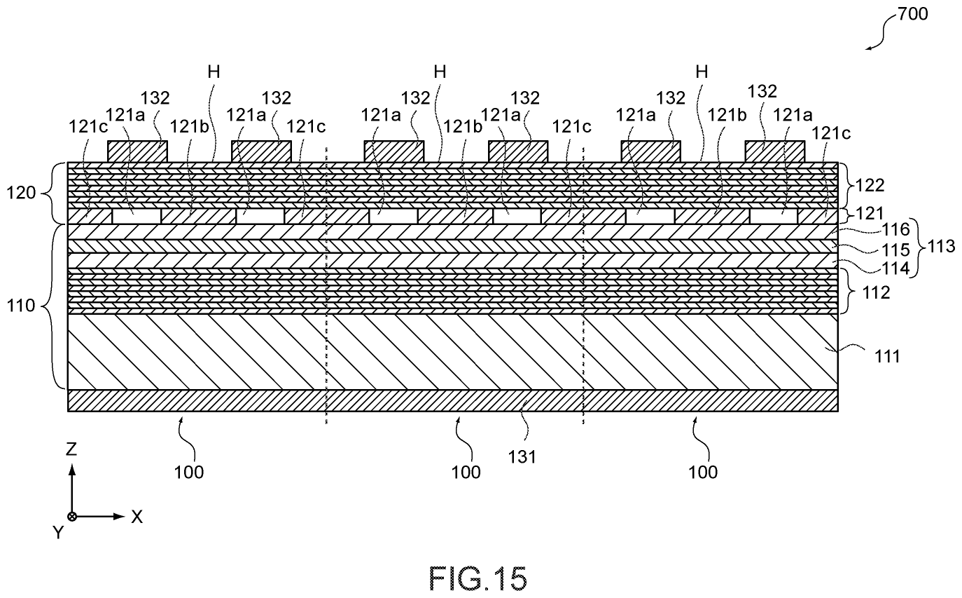

FIG. 15 is a cross-sectional view of a VCSEL element array 700 according to this embodiment. As shown in the figure, the VCSEL element array 700 is an array in which a plurality of VCSEL elements 100 is arranged. Although the VCSEL element array 700 includes three VCSEL elements 100 in FIG. 15, the number of VCSEL elements 100 only needs to be two or more and is not limited to three.

Each of the VCSEL elements 100 has the configuration described in the first embodiment, and the respective layers excluding the constriction layer 121 and the first electrode 132 are continuous layers between the plurality of VCSEL elements 100.

The VCSEL element array 700 can be formed by forming structures corresponding to the respective VCSEL elements 100 on the first substrate 110 and the second substrate 120 and then bonding the first substrate 110 and the second substrate 120 to each other. The constriction layer 121 can be formed with high accuracy using photolithography or the like, similarly to the first embodiment, and the pitch of the VCSEL element 100 can be narrowed. Further, by narrowing the pitch, the chip size is reduced even if the number of emitters is the same as that in the existing structure, and the yield can be improved.

Note that although the array of the VCSEL elements 100 according to the first embodiment has been shown here, also the VCSEL elements according to the second to sixth embodiments can be arrayed similarly.

### Eighth Embodiment

A VCSEL module according to an eighth embodiment of the present technology will be described.

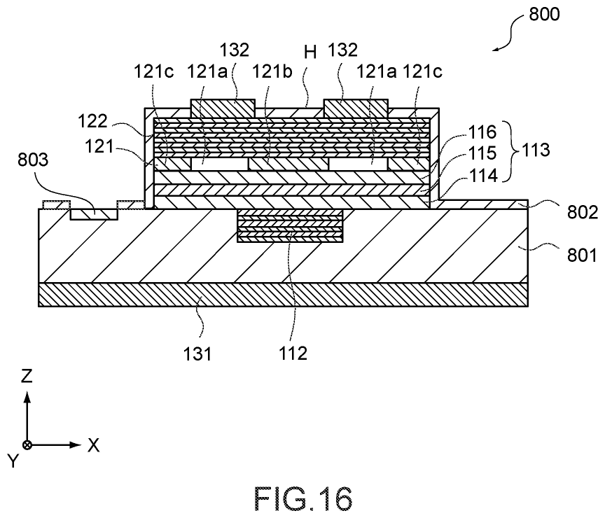

FIG. 16 is a cross-sectional view of a VCSEL module 800 according to this embodiment. As shown in the figure, the VCSEL module 800 includes a circuit substrate 801 in the VCSEL element 100 according to the first embodiment, instead of the base material 111. Further, the surface of the VCSEL element 100 is covered with a dielectric film 802 except for the second electrode 132.

The circuit substrate 801 is an IC (integrated circuit) substrate in which a wiring layer and an insulation layer are laminated, for example. A photodiode 803 is provided on the circuit substrate 801, and the VCSEL module 800 constitutes a time-of-flight (TOF) module using the VCSEL element 100 as a light-emitting element and the photodiode 803 as a light-receiving device.

The VCSEL module 800 can be prepared by bonding the first substrate 110 and the second substrate 120 to each other (see FIG. 9) and then removing the base material 111 and the base material 151 and bonding it to the circuit substrate 801. The VCSEL element 100 has a high affinity with silicon photonics and can be easily applied to a TOF module and a package.

Note that although the VCSEL module 800 including one VCSEL element 100 is shown in FIG. 16, the VCSEL element array as shown in the seventh embodiment can be mounted on a circuit substrate to obtain a VCSEL module. By combining with a circuit substrate, it is possible to independently drive each of the VCSEL elements 100.

Note that although a module of the VCSEL element 100 according to the first embodiment has been described here, the VCSEL elements according to the second to sixth embodiments can be modularized similarly.

It should be noted that the present technology may also take the following configurations.

(1) A vertical cavity surface emitting laser element, including:

a first substrate that is provided with a semiconductor layer including an active layer and a first distributed Bragg reflector (DBR) layer; and

a second substrate that is provided with a constriction layer and a second DBR layer, the constriction layer having a constriction region and an injection region having conductivity higher than that of the constriction region, the second substrate being bonded to the first substrate such that the constriction layer is adjacent to the semiconductor layer.

(2) The vertical cavity surface emitting laser element according to (1) above, in which

the constriction region and the injection region have a refractive index difference.

(3) The vertical cavity surface emitting laser element according to (1) or (2) above, in which

the constriction region is formed in a ring shape surrounding the injection region.

(4) The vertical cavity surface emitting laser element according to any one of (1) to (3) above, in which

the constriction region is a gap provided in the constriction layer.

(5) The vertical cavity surface emitting laser element according to any one of (1) to (4) above, in which

the injection region is formed of a conductive material, and

the constriction region is formed of a material obtained by applying non-conductive treatment to the conductive material.

(6) The vertical cavity surface emitting laser element according to (5) above, in which

the injection region is formed of GaAs, and

the constriction region is formed of a GaAs fluoride.

(7) The vertical cavity surface emitting laser element according to any one of (1) to (6) above, in which

the first substrate includes the semiconductor layer and the first DBR layer formed by crystal growth on a base material formed of GaAs, and

the second substrate includes the constriction layer and the second DBR layer formed by crystal growth on a base material formed of GaAs.

(8) The vertical cavity surface emitting laser element according to (7) above, in which

the active layer has a quantum well structure in which a barrier layer formed of GaAs and a quantum well layer formed of InGaAs are alternately laminated.

(9) The vertical cavity surface emitting laser element according to any one of (1) to (6) above, in which

the first substrate includes the semiconductor layer and the first DBR layer formed by crystal growth on a base material formed of GaAs, and

the second substrate includes the constriction layer and the second DBR layer formed by crystal growth on a base material formed of InP.

(10) The vertical cavity surface emitting laser element according to (9) above, in which

the active layer has a quantum well structure in which a barrier layer formed of InP and a quantum well layer formed of InGaAs, InGaAsP, or AlGaInAs are alternately laminated.

(11) The vertical cavity surface emitting laser element according to any one of (1) to (10) above, in which

the first DBR layer is a semiconductor DBR or a dielectric DBR, and

the second DBR layer is a semiconductor DBR or a dielectric DBR.

(12) The vertical cavity surface emitting laser element according to any one of (1) to (11) above, which emits a laser beam from a side of the second DBR layer.
(13) The vertical cavity surface emitting laser element according to any one of (1) to (11) above, which emits a laser beam from a side of the first DBR layer.
(14) A vertical cavity surface emitting laser element array, including:

a plurality of arranged vertical cavity surface emitting laser elements each including a first substrate that is provided with a semiconductor layer including an active layer and a first distributed Bragg reflector (DBR) layer, and a second substrate that is provided with a constriction layer and a second DBR layer, the constriction layer having a constriction region and an injection region having conductivity higher than that of the constriction region, the second substrate being bonded to the first substrate such that the constriction layer is adjacent to the semiconductor layer.

(15) A vertical cavity surface emitting laser module, including:

a circuit substrate; and

a vertical cavity surface emitting laser element that includes a first substrate that is provided with a semiconductor layer including an active layer and a first distributed Bragg reflector (DBR) layer, and a second substrate that is provided with a constriction layer and a second DBR layer, the constriction layer having a constriction region and an injection region having conductivity higher than that of the constriction region, the second substrate being bonded to the first substrate such that the constriction layer is adjacent to the semiconductor layer, and is mounted on the circuit substrate.

(16) A method of producing a vertical cavity surface emitting laser module, including:

forming a first substrate that is provided with a semiconductor layer including an active layer and a first distributed Bragg reflector (DBR) layer;

forming a second substrate that is provided with a constriction layer and a second DBR layer, the constriction layer having a constriction region and an injection region having conductivity higher than that of the constriction region; and

bonding the first substrate and the second substrate to each other such that the constriction layer is adjacent to the semiconductor layer.

(17) The method of producing a vertical cavity surface emitting laser element array according to (16) above, in which

the step of forming the second substrate further includes forming the constriction region and the injection region using photolithography.

### REFERENCE SIGNS LIST

100, 200, 300, 400, 500, 600 VCSEL element
110, 210, 310, 410, 510, 610 first substrate
120, 220, 320, 420, 520, 620 second substrate
112, 212, 312, 412, 512, 611 first DBR layer
122, 222, 322, 422, 522, 622 second DBR layer
113,213, 313, 413, 511, 612 semiconductor layer
115, 215, 315, 415, 515, 615 active layer
121, 221, 321, 421, 521, 621 constriction layer
700 VCSEL element array
800 VCSEL module
801 circuit substrate

1. A vertical cavity surface emitting laser element, comprising:
a first substrate that is provided with a semiconductor layer including an active layer and a first distributed Bragg reflector (DBR) layer; and
a second substrate that is provided with a constriction layer and a second DBR layer, the constriction layer having a constriction region and an injection region having conductivity higher than that of the constriction region, the second substrate being bonded to the first substrate such that the constriction layer is adjacent to the semiconductor layer.

2. The vertical cavity surface emitting laser element according to claim 1, wherein
the constriction region and the injection region have a refractive index difference.

3. The vertical cavity surface emitting laser element according to claim 1, wherein
the constriction region is formed in a ring shape surrounding the injection region.

4. The vertical cavity surface emitting laser element according to claim 1, wherein
the constriction region is a gap provided in the constriction layer.

5. The vertical cavity surface emitting laser element according to claim 1, wherein
the injection region is formed of a conductive material, and
the constriction region is formed of a material obtained by applying non-conductive treatment to the conductive material.

6. The vertical cavity surface emitting laser element according to claim 5, wherein
the injection region is formed of GaAs, and
the constriction region is formed of a GaAs fluoride.

7. The vertical cavity surface emitting laser element according to claim 1, wherein
the first substrate includes the semiconductor layer and the first DBR layer formed by crystal growth on a base material formed of GaAs, and
the second substrate includes the constriction layer and the second DBR layer formed by crystal growth on a base material formed of GaAs.

8. The vertical cavity surface emitting laser element according to claim 7, wherein
the active layer has a quantum well structure in which a barrier layer formed of GaAs and a quantum well layer formed of InGaAs are alternately laminated.

9. The vertical cavity surface emitting laser element according to claim 1, wherein
the first substrate includes the semiconductor layer and the first DBR layer formed by crystal growth on a base material formed of GaAs, and
the second substrate includes the constriction layer and the second DBR layer formed by crystal growth on a base material formed of InP.

10. The vertical cavity surface emitting laser element according to claim 9, wherein
the active layer has a quantum well structure in which a barrier layer formed of InP and a quantum well layer formed of InGaAs, InGaAsP, or AlGaInAs are alternately laminated.

11. The vertical cavity surface emitting laser element according to claim 1, wherein
the first DBR layer is a semiconductor DBR or a dielectric DBR, and
the second DBR layer is a semiconductor DBR or a dielectric DBR.

12. The vertical cavity surface emitting laser element according to claim 1, which emits a laser beam from a side of the second DBR layer.

13. The vertical cavity surface emitting laser element according to claim 1, which emits a laser beam from a side of the first DBR layer.

14. A vertical cavity surface emitting laser element array, comprising:
a plurality of arranged vertical cavity surface emitting laser elements each including a first substrate that is provided with a semiconductor layer including an active layer and a first distributed Bragg reflector (DBR) layer, and a second substrate that is provided with a constriction layer and a second DBR layer, the constriction layer having a constriction region and an injection region having conductivity higher than that of the constriction region, the second substrate being bonded to the first substrate such that the constriction layer is adjacent to the semiconductor layer.

15. A vertical cavity surface emitting laser module, comprising:
a circuit substrate; and
a vertical cavity surface emitting laser element that includes a first substrate that is provided with a semiconductor layer including an active layer and a first distributed Bragg reflector (DBR) layer, and a second substrate that is provided with a constriction layer and a second DBR layer, the constriction layer having a constriction region and an injection region having conductivity higher than that of the constriction region, the second substrate being bonded to the first substrate such that the constriction layer is adjacent to the semiconductor layer, and is mounted on the circuit substrate.

16. A method of producing a vertical cavity surface emitting laser module, comprising:
forming a first substrate that is provided with a semiconductor layer including an active layer and a first distributed Bragg reflector (DBR) layer;
forming a second substrate that is provided with a constriction layer and a second DBR layer, the constriction layer having a constriction region and an injection region having conductivity higher than that of the constriction region; and
bonding the first substrate and the second substrate to each other such that the constriction layer is adjacent to the semiconductor layer.

17. The method of producing a vertical cavity surface emitting laser element array according to claim 16, wherein
the step of forming the second substrate further includes forming the constriction region and the injection region using photolithography.
